(19) United States
(12) Patent Application Publication
(10) Pub. No.: US 2005/0196689 A1
(43) Pub. Date: Sep. 8, 2005

(54) Method for transferring a layout of an integrated circuit level to a semiconductor substrate

(76) Inventors: Christoph Nolscher, Dresden (DE); Rainer Pforr, Dresden (DE); Mario Hennig, Dresden (DE); Albrecht Kieslich, Radebeul (DE)

Correspondence Address: EDELL, SHAPIRO & FINNAN, LLC, 1901 RESEARCH BOULEVARD, SUITE 400, ROCKVILLE, MD, 20850, US

(21) Appl. No.: 11/071,571

(22) Filed: Mar. 4, 2005

(30) Foreign Application Priority Data
Mar. 5, 2004 (DE) DE 102004010902.8

(51) Int. Cl. G03F 9/00; G03F 7/20

(52) U.S. Cl. 430/30; 430/5; 430/396

(57) ABSTRACT

A mask level layout has an arrangement of lines and spaces with the spaces interconnected by a further space. The spaces are alternately acted upon with a phase deviation with respect to the spaces, where a phase edge between spaces acted upon differently arises in the region of the further space. Alternatively, the connecting space within the layout may be filled with dark regions. An additional space is inserted in a second layout representing a further mask of the same mask set. The additional space enables formation of an insulating region on a semiconductor substrate at the location where formation of a continuous isolation trench is not possible due to the phase edges or dark regions within originally connecting spaces of the first mask. The first mask can be embodied as a hybrid mask with structures according to the principle of alternating phase masks with a large process window.

### CROSS REFERENCE TO RELATED APPLICATIONS

This application claims priority under 35 USC §119 to German Application No. DE 102004010902.8, filed on Mar. 5, 2004, and entitled “Method for Transferring a Critical Layout of a Level of an Integrated Circuit to a Semiconductor Substrate,” the entire contents of which are incorporated herein by reference.

### FIELD OF THE INVENTION

The present invention relates to a method for transferring a critical layout of an integrated circuit level to a semiconductor substrate. The layout includes an arrangement of spaces in the vicinity of regions to be formed in an opaque or semitransparent fashion on a mask. The spaces are connected to one another by a further space provided laterally with respect to the arrangement. The arrangement may further be periodic.

### BACKGROUND OF THE INVENTION

In order to be able to achieve further advances in miniaturization in semiconductor technology, in particular in semiconductor memories, it is necessary for the so-called K₁ factor to be reduced ever further. This factor relates to the minimum feature size that can be attained in the image level of a projection system with respect to the light wavelength used and the numerical aperture of the projection system.

Since these quantities are predefined for an imaging, or are limited in the case of the numerical aperture, an improvement in the resolution quality can be attained only by employing so-called resolution enhancement techniques (RET). These include the use of different types of phase masks such as off-axis illumination, optical proximity correction (OPC), etc.

The RETs that are particularly effective lithographically require a subdivision of the layout that is in each case to be transferred to semiconductor substrates. This is due to the RET often exhibiting dependencies on the orientation and/or the size of the structures formed on the masks. Techniques adapted to a specific structure arrangement within the layout or the pattern correspondingly formed on the mask may exhibit no effect or a disadvantageous effect on an adjacent structure arrangement in the same layout or pattern. A structure-shared process window that results overall for the imaging may be adversely impaired.

Consequently, consideration has been given to division between two or more masks for imaging a common circuit level layout. The exposures have been transferred to the wafer in a sequential manner (double exposure). However, this in turn results in a dramatically reduced wafer throughput and, consequently, significantly higher costs in the area of lithography and for production of the electronic components. This is also the case for the levels that are the most demanding lithographically.

For memory circuits produced using so-called trench technology for the fabrication of capacitors, these are the levels for forming active regions (active areas), word lines (gate conductor), bit lines (metal 1 level) and the capacitor trenches (deep trenches). In this case, the memory cell array (array) and the peripheral structures (support) are typically separated from one another and imaged progressively onto the wafer via two different masks.

In order to reduce the production costs, solutions are being sought for replacing such double exposures by single exposures with tolerable or no losses with respect to the lithographic patterning quality.

Attempts are currently being made to solve the problem by employing special off-axis techniques (oblique light illumination) tailored to the layout. However, the problem still exists and it is necessary to accept a compromise between either a significantly degraded imaging characteristic of the cell array or a significantly degraded imaging of the peripheral structures. A technical solution which does not lead to an increased mask error enhancement factor (MEEF) for the cell array structures and ultimately to a poorer overall lithographic imaging behavior is not available at the present time. The mask error enhancement factor reflects nonlinear behavior in the transfer of errors present on the mask to the semiconductor substrate in the region of the resolution limit of the projection system being employed.

### SUMMARY OF THE INVENTION

The present invention provides a method to apply resolution enhancement techniques (RET) to the transfer of a layout to a semiconductor substrate without limitations with regard to the imaging characteristics of individual structure portions.

Furthermore, the present invention reduces the costs and the complexity for the projection of layouts of integrated circuit levels onto semiconductor substrates, and makes it possible to carry out single exposures for circuit levels.

The present invention provides a method for transferring a layout of an integrated circuit level to a semiconductor substrate. The layout includes an arrangement of transparent spaces which are partly surrounded by regions to be formed in an opaque or semitransparent fashion on a first mask. The spaces are connected to one another by a further transparent space, preferably provided laterally with respect to the arrangement. The method includes the steps of: providing the layout for fabrication of the first mask; assigning a phase deviation surplus to every second space of the spaces in order to form an alternating arrangement of spaces; removing the further space from the layout and replacing it by a region to be formed in an opaque or semitransparent fashion on the first mask, so that the spaces of the arrangement are separated from one another; providing a further layout for fabrication of a second mask; establishing at least one additional space in the further layout which is surrounded by regions to be formed in opaque or semitransparent fashion and the position and area of which at least partly, correspond to those of the space that was removed in the first layout; transferring the first layout to the first mask and the second layout to the second mask; and respectively carrying out a sequence of steps for the first and second masks including projecting the mask into a photosensitive layer on the semiconductor substrate for the purpose of forming a pattern and developing and transferring the pattern into an underlying layer.

The layout of an integrated circuit level includes a number of spaces. This layout is initially present in an electronically stored form. Lines and spaces, and more generally, light and dark regions, are usually represented in each case by different color, brightness or transparency values. From a layout, in various method steps known to the knowledgeable person skilled in the art, control instructions are created for mask writers for forming the patterns in photosensitive layers arranged on the photomasks.

Furthermore, the spaces of such an arrangement are assumed to be connected by a further space. These patterns are often found, for example, in layouts when electrically conductive tracks leading out in fingermark fashion are to be produced by the lines on the semiconductor substrate, where the tracks are delimited by insulation regions formed with the aid of the space running, for example, laterally with respect to the arrangement.

If such a structure is present, then, it is possible to implement an RET technique by applying the principle of alternating phase masks to the arrangement. Opaque or essentially nontransparent lines (ridges) are alternately delimited by transparent spaces with a phase deviation surplus that differs by one-hundred eighty degrees. A first space of the arrangement has, for example, a phase deviation of zero degrees, while a space adjacent thereto has a phase deviation of one-hundred eighty degrees. In the ideal case of a ratio of the width of lines to that of the spaces being 1:1, a considerable contrast accentuation is obtained during imaging on the wafer.

In the case of the related art, there is a problem that if the lines (i.e., the structures, of the periodic arrangement that are to be formed in an opaque or semitransparent fashion on the mask) are delimited on at least one side of the arrangement, the transparent regions of the spaces have to make contact with each other with a different phase deviation surplus on precisely this side. At the boundary line between these regions, there exists a phase edge which, in the case of projecting imaging onto a semiconductor substrate, leads to shading and thus to undesirable structure formation at these positions.

The formation of spaces that are not connected to one another is made possible in accordance with the present invention since the connecting space is a constituent part of the pattern to be formed on the semiconductor substrate. For this purpose, although the space is removed in this layout, the space is added again in a further layout. This preferably involves a layout of a further level (to be imaged anyway) of the same integrated circuit with a pattern comprising structure elements forming electronically functional components. In this case, the respective forms of the removed and added spaces do not have to be identical but the positions should essentially correspond in order to obtain the desired effect.

Consequently, it is possible to image the line and space structure according to the principle of alternating phase masks on the mask corresponding to the first layout. Since it is possible to retain other structures of the layout on the mask, the formation of a hybrid phase mask is thus proposed according to the present invention.

With the space structure that is extracted from the first layout and inserted into the second layout, the adaptations that are still necessary for the pattern to be created overall on the substrate are performed on the semiconductor substrate. In one example, trenches filled with insulating material are in each case formed in the substrate by the spaces on the masks. A space that is arranged laterally with respect to the periodic arrangement and connects the spaces of the arrangement is replaced by opaque areas in the first layout, and placed into a second layout at the same position. With respect to the second layout, during the projection of a mask, maskings of a resist situated on the substrate are formed, where, as in the application of the first layout, trenches can be etched in the substrate. Further, the mask fabricated with the layout is applied to the same area patch of the substrate as is the case in the application of the first layout.

The purpose of implementing the further space that connects the spaces of the arrangement in the second layout is to compensate for the lack of the electrical properties formed by it in the pattern formed by the first layout on the substrate. In particular, the mask provided with the second layout may also be provided, in the component fabrication cycle, before the mask with the first layout for projection onto the substrate. The following example serves as illustration. A particularly advantageous configuration provides for making interventions in the layout of a mask that is to be used in the cycle of fabricating semiconductor memories for the formation of the capacitor trenches (deep trenches (hereinafter DT mask)). This makes it possible, in the case of a mask that is subsequently used for the formation of active regions (active areas (hereinafter AA mask)), to form the periodically arranged spaces that are present in many instances according to the principle of the alternating phase mask. For this purpose, the further space that connects the spaces of the arrangement is removed from the first layout of the AA mask (i.e., replaced by dark structures for forming opaque or semitransparent areas). The periodically arranged spaces are accordingly enclosed by the absorber or the dark structures. In the context of mask fabrication, these can then be acted upon alternately with a phase deviation of approximately one-hundred eighty degrees, for example, via quartz etching.

Since the DT mask, like the AA mask, is applied to the patterning of the same silicon substrate, and the sequences of steps of the processing subsequent to the exposure in each case provide the deposition of insulating layers, it is possible to implement the laterally running space in the second layout of the DT mask. This presupposes that the second layout has no further structures at the relevant position.

Consequently, it is not necessary to establish a further mask (not previously provided in the cycle) with the second layout, as would be the case for instance with double or multiple exposures. The implementation of the further space (e.g., running laterally with respect to the arrangement of spaces) is combined in a mask of the existing set of masks, together with other structure elements serving as forming components of the integrated circuit (e.g., the trench capacitor pairs of the DT mask). Therefore, no additional expenditure is incurred with regard to costs, production and apparatus time.

The structure elements of the layout converted according to the principle of alternating phase masks result in a significantly improved linewidth stability (critical dimension) compared with other mask techniques, such as chromium or halftone phase masks, because the lithographic process window of such structures is significantly enlarged. The method according to the present invention is employed wherever a sufficient process window cannot be obtained with mask elements comprising chromium or halftone phase mask material.

The present invention preferably provides a method for transferring a layout of an integrated circuit level to a semiconductor substrate. The layout includes an arrangement of transparent spaces which are partly surrounded by regions to be formed in an opaque or semitransparent fashion on a first mask and spaces connected to one another by a further transparent space preferably provided laterally with respect to the arrangement. The method comprises the steps of: providing the layout for fabrication of the first mask; assigning a phase deviation surplus to every second space of the spaces for the purpose of forming an alternating arrangement of spaces, so that phase boundaries between the spaces that are acted upon with the phase deviation and the spaces that are not acted upon with the phase deviation arise at the space or within the connecting space; removing the further space from the layout and replacing it by a region to be formed in an opaque or semitransparent fashion on the first mask, so that the spaces of the arrangement are no longer connected to one another; providing a further layout for fabrication of a second mask; establishing at least one additional space in the further layout, which is surrounded by regions to be formed in an opaque or semitransparent fashion and the position and area of which at least partly correspond to those of the phase boundaries that arose in the first layout; transferring the first layout to the first mask and the second layout to the second mask; and respectively carrying out a sequence of steps for the first and second mask including projecting the mask into a photosensitive layer on the semiconductor substrate for the purpose of forming a pattern, and developing and transferring the pattern into an underlying layer.

This alternative embodiment of the invention is based on the concept, as a modification in comparison with the first alternative, of omitting the step of filling the connecting space via dark regions. This inevitably results in phase edges in the region of the connecting space, depending on the extent to which the areas of the spaces that have been acted upon in respect of phase project beyond these into the connecting space. The effect of the phase edges is similar to that in the case of filling with dark regions. For example, during imaging onto the semiconductor substrate, bridges are fabricated between regions that are actually to be formed in a manner insulated from one another. These are to be separated, as in the case of the first embodiment, via a second layout with an additional space provided at the corresponding position (the phase edges in the context of a further projection).

During this projection (e.g., before or after the transfer of the first mask including subsequent processing), in an analogous manner, a region that is to be formed in insulating fashion is etched into a further layer lying below the exposed photosensitive layer on a substrate. An underlying layer may also denote the substrate itself.

### BRIEF DESCRIPTION OF THE DRAWINGS

The invention will now be explained in more detail on the basis of an exemplary embodiment with the aid of the following drawings, in which:

FIG. 1 shows a detail from superimposed layouts of the AA and DT mask levels of a memory chip using trench capacitor technology, according to the related art;

FIG. 2 shows superimposed layouts as in FIG. 1, in which case a further space structure according to the present invention is introduced in the DT mask level and replaces a laterally running space in the AA mask level;

FIG. 3 shows the layout of the AA mask level according to the present invention from FIG. 2, in which further chromium dark structures and phase-shifting regions are introduced according to the principle of alternating phase masks;

FIG. 4 shows the layout of the AA mask level from FIG. 3 with supplementary sub-resolution phase assist structures;

FIG. 5 shows a modification according to the present invention of the example shown in FIG. 3;

FIG. 6 shows a flow diagram with a sequence of the method according to the present invention in accordance with the exemplary embodiment shown in FIG. 3;

FIG. 7 shows a flow diagram with a sequence of the method according to the present invention in accordance with the exemplary embodiment shown in FIG. 5.

### DETAILED DESCRIPTION OF THE INVENTION

An exemplary embodiment of the invention will be explained on the basis of an AA mask level used for fabricating a memory chip. The memory chip is embodied using trench capacitor technology.

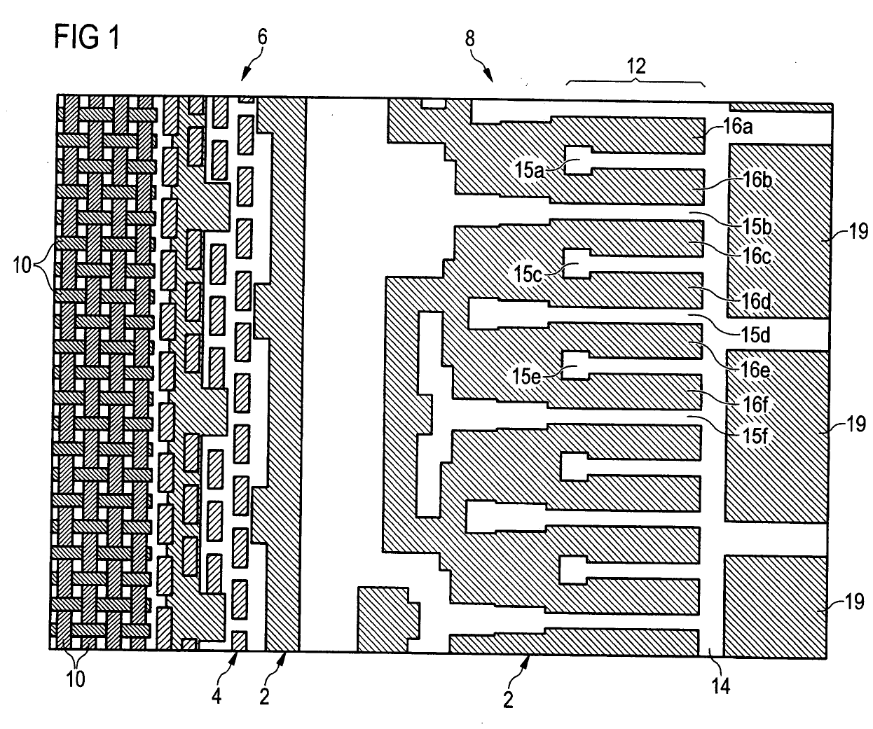

FIG. 1 shows a detail from a first layout 2 and a second layout 4, superimposed with the latter, from the edge of the memory cell array 6 (left-hand side of FIG. 1) with an adjoining periphery, the so-called support structures 8 (right-hand side). The first layout 2 represents the pattern of active regions that is to be imaged conventionally via an AA mask level on the semiconductor substrate. In the figures, regions of the AA mask level that are to be fabricated in an opaque or semitransparent fashion, that is to say light-shading to a greater or lesser extent on the mask, are illustrated with a gray background, while the essentially transparent spaces are shown white.

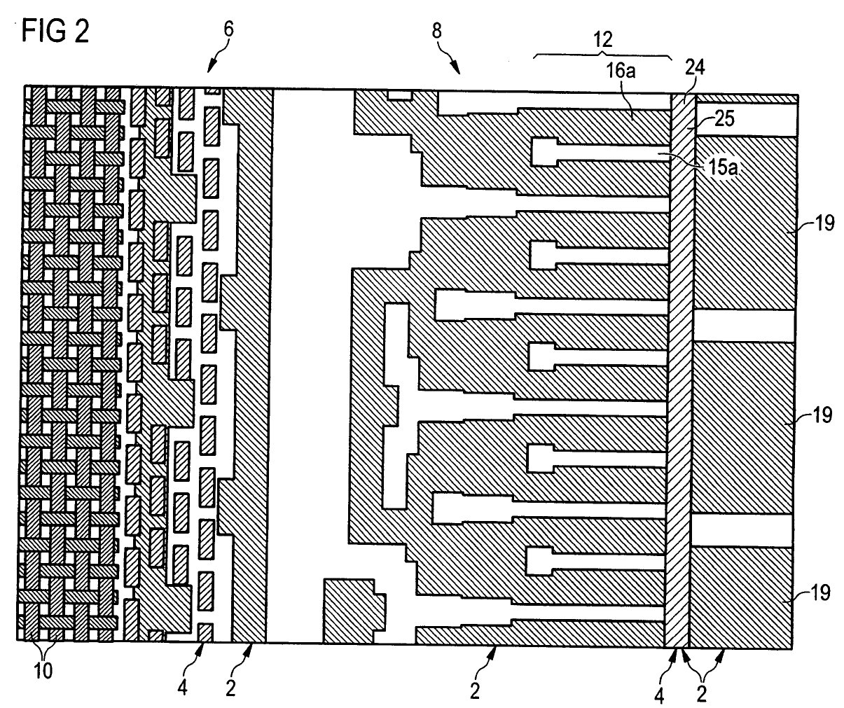

The superimposed second mask layout 4 represents the DT mask level. It solely comprises the structure elements of the trench capacitor structures within the memory cell array 6. The structure elements of the DT mask level are to be formed in transparent fashion on the mask; for the sake of clarity, FIG. 1 shows these tonally inverse with respect to the first layout 2 as structures with a black background. That is to say that opaque regions of the DT mask level are indicated without any color steps (as transparent) in FIGS. 1 and 2.

FIG. 1 describes electronically stored mask layouts 2, 4 in accordance with the related art. Conventionally, each of the two layouts, as shown in FIG. 1, would have to be imaged on a respective mask.

In accordance with the method of the present invention, in the first layout 2 of the AA mask level that is provided, it is possible to first seek structure portions which are suitable for isolated formation on the mask, according to the principle of alternating phase masks, in order to obtain an improvement in the process window for the overall pattern. In this case, the periodic arrangement 12 of spaces l5a-15f, etc. in a pattern comprising lines 16a-16f, etc. is selected, the periodic arrangement being present in the peripheral region 8.

The lines 16a-16f, etc., formed as opaque on the mask, serve for shading the substrate surface during projection, so that the corresponding regions remain on the substrate as a result of an etching that is carried out after the projection. After a further implantation is carried out, the regions, by way of example, become parts of electrically conductive tracks or become active regions of transistors which can be contact-connected by interconnects of a next higher level.

A space 14 running laterally, with respect to the periodic arrangement, is connected to the spaces 15a-15f, etc., so that the active regions, that are respectively formed on the substrate, are insulated from further active regions which arise on account of further dark structures 19 shown on the right in FIG. 1. The space 14 prevents an implementation of the alternating phase mask technique in the periodic arrangement 12 since regions having a different phase deviation surplus should not adjoin one another.

FIG. 2 shows the result of a first step for revising the first layout 2, but also the second layout 4, with the aim of enabling the fabrication of a hybrid mask according to the invention. In the first layout of the AA mask level, the space 14 is extracted (i.e., filled with a dark region 24). The dark region 24 separates the spaces 15a-15f, etc. in the AA mask level from one another (i.e., they are no longer connected to one another).

A further layout of a further mask level for the same set of masks is then selected. This further mask level is used to form insulating structures in the current layer level or substrate surface, after a projection. This is the DT mask level. Although a conductive filling is deposited, during the corresponding postprocessing, into the trenches effected by the transparent structure elements 10, a layer for forming an insulating collar (i.e., insulation collar) is usually additionally deposited in the region of trench depths that is of interest (namely the depths of a typical shallow trench isolation (STI)).

Structures that are defined as transparent in this further pattern selected as a second layout, are accordingly converted into structures that are insulating at least in a superficial region on the substrate after a projection. A transparent structure element, or a space 25, is then inserted in the second layout that is selected in accordance with these standpoints. Space 25 has a position and an area in the second layout of the DT mask level which corresponds to those of the extracted space 14 in the first layout of the AA mask level in such a way as to achieve the desired property of insulating the periodically arranged active regions from the further regions 19.

The present invention furthermore provides for enhancing the electronically functional insulation during post processing by preventing effects of outdiffusion (e.g., buried strap outdiffusion) in the extended and elongated trench region which arises as a result of the inserted space 25 on the substrate. The lithographic patterning may be effected by the use of cost-effective lithographic techniques (e.g., via i-line lithography). Steps such as an implantation and/or diffusion, resist removal and substrate cleaning are also provided.

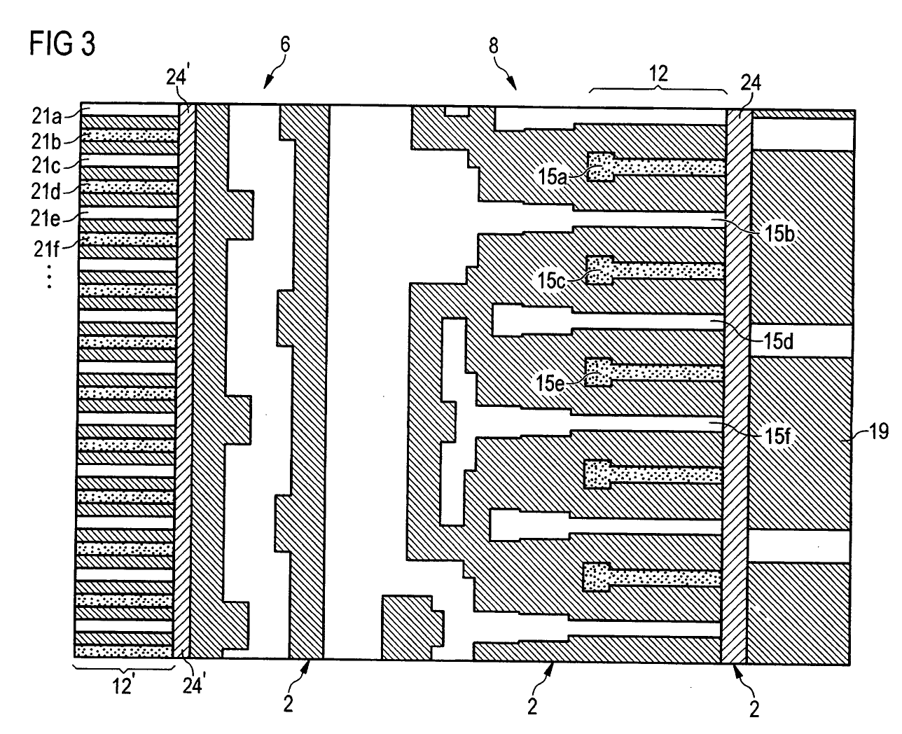

In a further step of the method according to the present invention, spaces 15a, 15c, 15e, etc. are alternately acted upon with a phase deviation of one-hundred eighty degrees with respect to the spaces 15b, 15d, 15f, etc., as can be seen in FIG. 3. Only the first layout 2 of the AA mask level is shown as an excerpt in FIG. 3.

As a result of the introduction of the phase deviation surplus, the corresponding arrangements 12 of the type of a simple chromium mask are converted into those of an alternating phase mask. The structure elements 15, 16 influenced by this experience a significant increase in their lithographic process window and also a significant reduction of the MEEF (mask error enhancement factor). As a result, these structure elements are produced with significantly higher linewidth stability on the wafer. Consequently, the product yield increases and the costs for fabricating the relevant electronic components decrease.

It can be seen on the left-hand side of FIG. 3 that structure element arrangements 12′ of the memory cell array in the first layout have also been treated in analogous steps. A relevant space has been filled with the dark region 24′ and the spaces 21b, 21d, 21f, etc. have alternately been acted upon with a phase deviation of one-hundred eighty degrees with respect to the spaces 21a, 21c, 21e, etc. The second layout 4 is analogously supplemented by a corresponding space at the essentially matching position.

By virtue of both densely packed periodic arrangements 12′ of the memory cell array and imaging-critical periodic structure arrangements 12 in the region of the support electronics being embodied according to the principle of the alternating phase mask, while all the remaining structures are embodied as a chromium or halftone phase mask, the so-called overlapping lithographic process window of these structures is improved in comparison with the related art to such an extent that a single exposure can be carried out and a high degree of linewidth stability can be achieved across the image field of the exposure system for all structures. This leads to a significant increase in the manufacturing productivity and, consequently, to an appreciable reduction of costs. Compared with the alternative methods mentioned above, a significantly larger lithographic process window and, consequently, an increased product yield are achieved, which likewise result in significantly reduced costs.

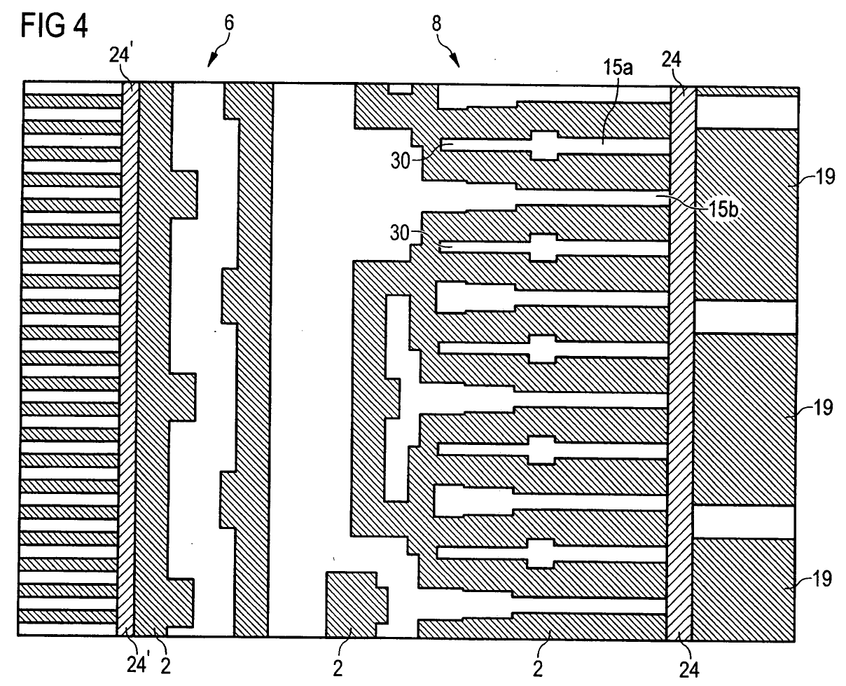

FIG. 4 shows, in a supplementation of FIG. 3, the combination of the periodic arrangement 12 with an application of sub-resolution phase assist structures (SRAF), also referred to as assist structures. These structures are not themselves printed in the resist, but accentuate the aerial image contrast of the adjacent bright structures and improve the linewidth stability thereof.

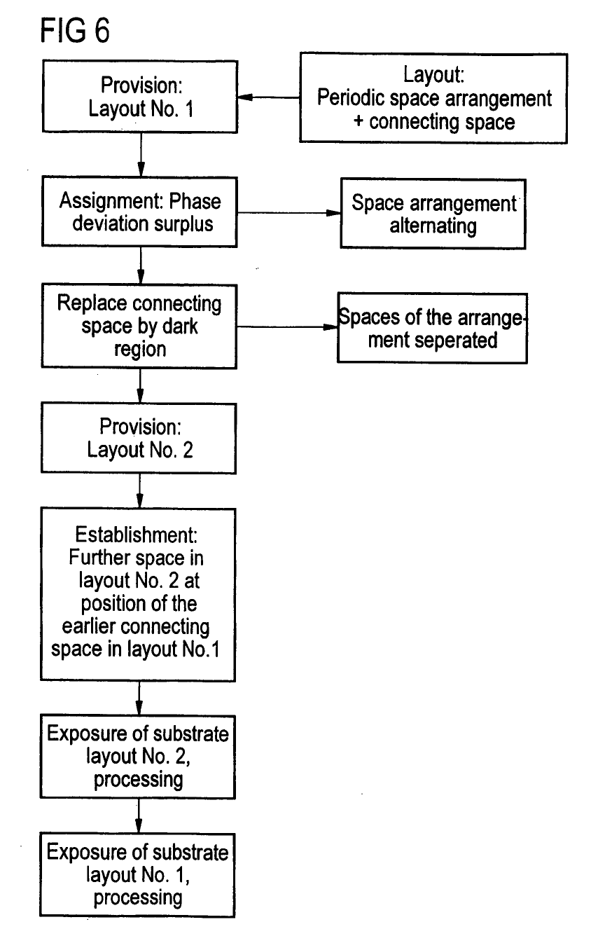

FIG. 6 shows, in a flow diagram, the sequence of the method according to the present invention in accordance with the exemplary embodiment shown in FIG. 3.

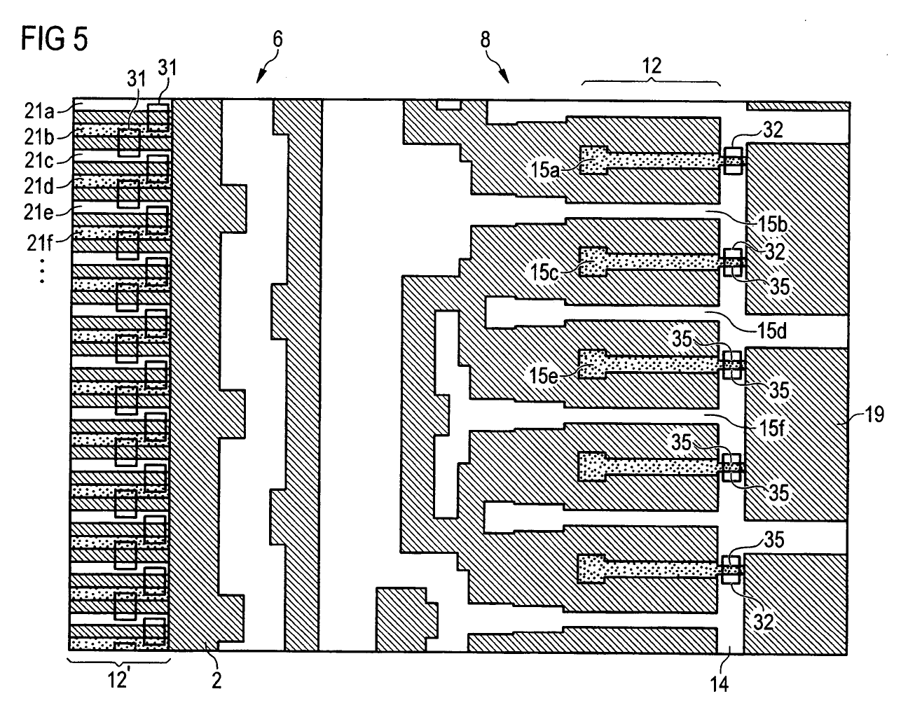

FIG. 5 shows, in a modification of FIG. 3, an alternative embodiment of the present invention, in which the space 14 in the first layout 2 is not filled with dark regions 24. Instead, phase edges 35 arise there, which, as a result of the extending of the transparent spaces 15a, 15c, 15e that were acted upon in respect of phase, are situated within the space 14 that connects the spaces. In the second layout 4, spaces (31, 32) are indicated by rectangles with borders and spaces 32 are established precisely at the positions of the phase edges 35 in a manner overlapping the latter.

In the region of the cell array 6, it is possible to separate the lines between the spaces 21a-21f from the peripheral region 8 by spaces 31 corresponding to the trench capacitor spaces 10. It is also possible, as in the peripheral region 8, in the cell array 6 to lengthen the spaces 21b, 21d, 21f that were acted upon in respect of phase into a connecting space (not shown in FIG. 5 but analogous to the space 14 in the peripheral region) and to superimpose on the resulting phase edges further spaces 31, positioned precisely above the space, in the second layout 4.

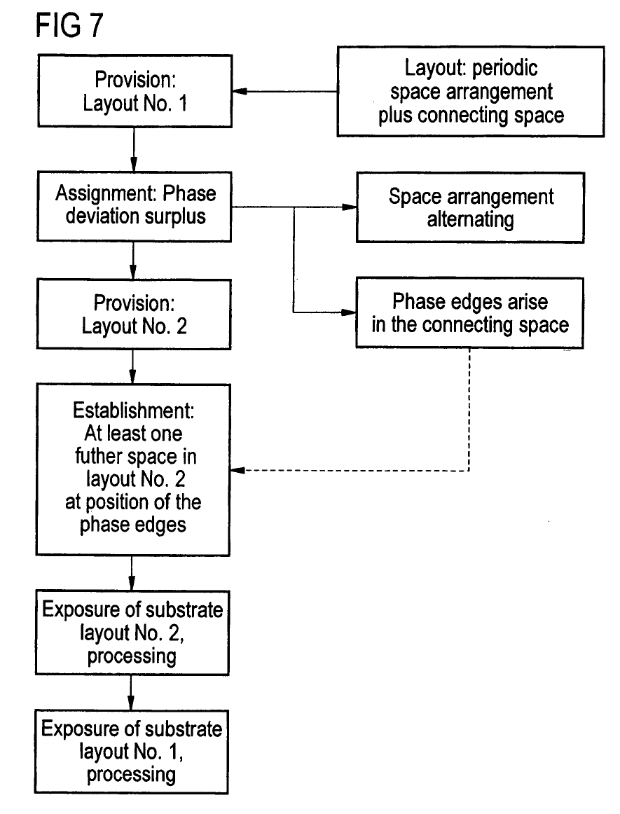

FIG. 7 shows, in a flow diagram, the sequence of the method according to the present invention in accordance with the modification without filling the connecting space with dark structures, but with further spaces in the second layout which have to cover only the position of the phase edges and no longer the entire earlier space in order to achieve a corresponding effect on the substrate.

In the exemplary embodiment, this effect achieves an insulation at the location of the earlier space on the mask after the exposed regions have been transferred into the substrate by etching. The spaces that have also been formed on the semiconductor substrate by etching are filled with electrically insulating material. This requires further processing steps such as deposition, planarization, etc.

The phase edges imaged with the first layout as shadow structures lead, on the semiconductor substrate, to electrically conductive bridges between active contact-connection regions, which is to be suppressed. Therefore, in accordance with this modification of the invention, it is only at these positions that a prior formation of insulation regions must be made possible in the second layout by establishing one or, depending on the number of phase edges, a plurality of further spaces.

It lies within the scope of the invention for all structures which cannot be provided with an imaging-enhancing phase structure to be embodied as a halftone phase mask.

It is to be understood that like reference numerals in the various figures are utilized to designate like components. Further, having described preferred embodiments of the present invention, it is believed that other modifications, variations and changes will be suggested to those skilled in the art in view of the teachings set forth herein. It is therefore to be understood that all such variations, modifications and changes are believed to fall within the scope of the present invention as defined by the appended claims.

### LIST OF REFERENCE SYMBOLS

2 First layout, AA mask level
4 Second layout, DT mask level
6 Memory cell array
8 Peripheral structures, support region
10 Structure elements for forming trench capacitors
12 Periodic arrangement
14 Laterally arranged space in AA mask level
15 Spaces in periodic arrangement (support region)
16 Lines in periodic arrangement
21 Spaces in periodic arrangement (memory cell array)
24 Dark regions for filling the connecting space
25 Inserted spaces in DT mask level
31 Inserted spaces in DT mask level (memory cell array: alternative)
32 Inserted spaces in DT mask level (periphery: alternative)
35 Phase edges

1. A method for transferring a layout of an integrated circuit level to a semiconductor substrate, wherein the layout includes an arrangement of transparent spaces for imaging on a first mask with the transparent spaces being at least partly surrounded by regions that are formed in an opaque or semitransparent fashion on the first mask and being connected to one another by a further transparent space provided laterally with respect to the arrangement, the method comprising:
providing the circuit level layout for fabrication of the first mask;
assigning a phase deviation that differs from an average phase deviation of the first mask to every other space in order to form an arrangement of spaces with an alternating value for the phase deviation;
removing the lateral space from the circuit level layout and replacing that space by a region formed in an opaque or semitransparent fashion on the first mask to prevent the transparent spaces of the arrangement from being connected to one another;
providing a second layout of a second level of the integrated circuit for fabrication of a second mask;
establishing at least one additional space in the second layout that is surrounded by regions formed in an opaque or semitransparent fashion and the position and area of which at least partly correspond to those of the removed lateral space;
transferring the circuit level layout to the first mask and the second layout to the second mask; and
for each of the first and second masks, projecting the mask into a photosensitive layer on the semiconductor substrate for the purpose of forming a pattern and developing and transferring the pattern into an underlying layer.

2. The method as claimed in claim 1, wherein the patterns transferred into an underlying layer are at least partly filled with insulating material in each case after transfer.

3. The method as claimed in claim 1, wherein the phase deviation is assigned to spaces with a difference of approximately 180 degrees with respect to other spaces that are not acted upon.

4. The method as claimed in claim 1, wherein the arrangement forms a periodic pattern of transparent spaces and opaque or semitransparent lines.

5. The method as claimed in claim 1, wherein the transparent spaces form electrically insulating regions in the circuit in response to the projection onto the semiconductor substrate of the circuit level layout transferred to the first mask and a subsequent processing of the substrate.

6. The method as claimed in claim 1, wherein the projection steps are carried out in a photosensitive layer applied on the semiconductor substrate, and between the projection steps, the exposed photosensitive layer is developed for the purpose of carrying out a further method step, including an etching step.

7. The method as claimed in claim 1, wherein the second layout is selected in the event the second mask formed with the second layout, in the case of transfer to the semiconductor substrate, patterns an identical area patch to the first mask formed with the circuit level layout.

8. The method as claimed in claim 1, wherein the second layout is used for forming insulating regions on the semiconductor substrate.

9. The method as claimed in claim 1, wherein the circuit level layout represents a mask level for the formation of active regions and the mutual insulation thereof.

10. The method as claimed in claim 1, wherein the second layout represents a mask level for forming trench capacitors in the semiconductor substrate, and the second mask formed with the second layout is transferred into the photosensitive layer on the semiconductor substrate before the first mask formed with the circuit level layout.

11. A method for transferring a layout of an integrated circuit level to a semiconductor substrate, wherein the layout includes an arrangement of transparent spaces for imaging on a first mask and which are at least partly surrounded by regions formed in an opaque or semitransparent fashion on the first mask with the transparent spaces being connected to one another by a further transparent space provided laterally with respect to the arrangement, the method comprising:
providing the circuit level layout for fabrication of the first mask;
assigning a phase deviation that differs from an average phase deviation of the first mask to every other space of the transparent spaces for the purpose of forming an arrangement of spaces with an alternating value for the phase deviation to enable phase boundaries between the spaces that are acted upon with the phase deviation and other spaces that are not acted upon with the phase deviation to arise at the space or within the connecting space;
removing the lateral space from the circuit level layout and replacing that space by a region formed in an opaque or semitransparent fashion on the first mask to prevent the transparent spaces of the arrangement from being connected to one another;
providing a second layout of a second level of the integrated circuit for fabrication of a second mask;
establishing at least one additional space in the second layout that is surrounded by regions formed in an opaque or semitransparent fashion and the position and area of which at least partly correspond to those of the phase boundaries that arose in the circuit level layout;
transferring the circuit level layout to the first mask and the second layout to the second mask; and
for each of the first and second masks, projecting the mask into a photosensitive layer on the semiconductor substrate for the purpose of forming a pattern and developing and transferring the pattern into an underlying layer.

12. The method as claimed in claim 11, wherein the patterns transferred into the underlying layer are at least partly filled with insulating material in each case after transfer.

13. The method as claimed in claim 11, wherein the phase deviation is assigned to spaces with a difference of approximately 180 degrees with respect to other spaces that are not acted upon.

14. The method as claimed in claim 11, wherein the arrangement forms a periodic pattern of transparent spaces and opaque or semitransparent lines.

15. The method as claimed in claim 1, wherein the transparent spaces form electrically insulating regions in the circuit in response to the projection onto the semiconductor substrate of the circuit level layout transferred to the first mask and a subsequent processing of the substrate.

16. The method as claimed in claim 11, wherein the projection steps are carried out in a photosensitive layer applied on the semiconductor substrate, and between the projection steps, the exposed photosensitive layer is developed for the purpose of carrying out a further method step, including an etching step.

17. The method as claimed in claim 11, wherein the second layout is selected in the event the second mask formed with the second layout, in the case of transfer to the semiconductor substrate, patterns an identical area patch to the first mask formed with the circuit level layout.

18. The method as claimed in claim 11, wherein the second layout is used for forming insulating regions on the semiconductor substrate.

19. The method as claimed in claim 11, wherein the circuit level layout represents a mask level for the formation of active regions and the mutual insulation thereof.

20. The method as claimed in claim 11, wherein the second layout represents a mask level for forming trench capacitors in the semiconductor substrate, and the second mask formed with the second layout is transferred into the photosensitive layer on the semiconductor substrate before the first mask formed with the circuit level layout.
